(19) United States
(12) Patent Application Publication
(10) Pub. No.: US 2024/0284705 A1
(43) Pub. Date: Aug. 22, 2024

(54) DISPLAY APPARATUS AND METHOD OF MANUFACTURING THE SAME

(71) Applicant: Samsung Display Co., Ltd., Yongin-si (KR)

(72) Inventors: Kiseok Choi, Yongin-si (KR); Myounggeun Cha, Yongin-si (KR); Jongjun Baek, Yongin-si (KR); Heekyun Shin, Yongin-si (KR); Yonghoon Yang, Yongin-si (KR)

(21) Appl. No.: 18/486,396

(22) Filed: Oct. 13, 2023

(30) Foreign Application Priority Data
Feb. 17, 2023 (KR) 10-2023-0021590

(51) Int. Cl. H10K 59/121; H10K 59/12; H10K 59/122

(52) U.S. Cl. CPC H10K 59/1213; H10K 59/1201; H10K 59/122; H10K 2102/103

(57) ABSTRACT

A display apparatus includes: a first substrate including a polymer resin; a first barrier layer on the first substrate and including a portion doped with ions, wherein the portion includes an upper surface of the first barrier layer; a second substrate on the upper surface of the first barrier layer and including a polymer resin; a buffer layer on the second substrate; a first thin-film transistor on the buffer layer; and a light-emitting diode electrically connected to the first thin-film transistor.

### CROSS-REFERENCE TO RELATED APPLICATION

The present application claims priority to and benefits of Korean Patent Application No. 10-2023-0021590, filed on Feb. 17, 2023, in the Korean Intellectual Property Office, the entire disclosure of which is incorporated herein by reference.

### BACKGROUND

### 1. Field

Aspects of one or more embodiments relate to a display apparatus and a method of manufacturing the display apparatus.

### 2. Description of the Related Art

Recently, the various uses of display apparatuses has diversified. For example, as display apparatuses have become relatively thinner and lighter over time, their range of uses has gradually been expanded. Among them, portable, thin, flat panel-type flexible display apparatuses are in the spotlight. A flexible display apparatus is generally lightweight, has strong impact resistance, and has excellent portability because the flexible display apparatus may be folded or rolled and stored.

Because it may be difficult to implement flexibility in a glass substrate, a flexible display apparatus uses a base film including polymer resin and the like as a substrate.

The above information disclosed in this Background section is only for enhancement of understanding of the background and therefore the information discussed in this Background section does not necessarily constitute prior art.

### SUMMARY

Aspects of one or more embodiments include a display apparatus in which adhesive force between a substrate including a transparent polymer resin and a barrier layer is improved, and thus, a floating or exfoliation phenomenon between the substrate and the barrier layer may be prevented or reduced. However, this characteristic is an example, and embodiments according to the present disclosure are not limited thereto.

Additional aspects will be set forth in part in the description which follows and, in part, will be apparent from the description, or may be learned by practice of the presented embodiments of the disclosure.

According to one or more embodiments, a display apparatus includes a first substrate including a polymer resin, a first barrier layer on the first substrate and including a portion doped with ions, wherein the portion includes an upper surface of the first barrier layer, a second substrate on the upper surface of the first barrier layer and including a polymer resin, a buffer layer on the second substrate, a first thin-film transistor on the buffer layer, and a light-emitting diode electrically connected to the first thin-film transistor.

According to some embodiments, the first barrier layer may include at least one of silicon oxide, silicon nitride, or silicon oxynitride.

According to some embodiments, the ions may include fluorine ions or boron ions.

According to some embodiments, the second substrate may include transparent polyimide.

According to some embodiments, adhesive force of the first barrier layer may be 200 gf/inch or more.

According to some embodiments, the first thin-film transistor may include a first semiconductor layer including a silicon semiconductor and a first gate electrode insulated from the first semiconductor layer.

According to some embodiments, the display apparatus may further include an insulating layer covering the first gate electrode, and a second thin-film transistor on the insulating layer and including a second semiconductor layer and a second gate electrode insulated from the second semiconductor layer, wherein the second semiconductor layer includes an oxide semiconductor.

According to some embodiments, the display apparatus may further include a bottom metal layer between the second substrate and the buffer layer.

According to some embodiments, the display apparatus may further include a second barrier layer between the second substrate and the buffer layer.

According to one or more embodiments, a method of manufacturing a display apparatus includes preparing a first substrate including a polymer resin, forming a first barrier layer on the first substrate, doping an upper surface of the first barrier layer with ions such that a portion including the upper surface of the first barrier layer is ion-doped, forming a second substrate on the upper surface of the first barrier layer, wherein the second substrate includes a polymer resin, forming a buffer layer on the second substrate, and forming a first thin-film transistor and a light-emitting diode on the buffer layer, wherein the light-emitting diode is electrically connected to the first thin-film transistor.

According to some embodiments, the first barrier layer may include at least one of silicon oxide, silicon nitride, or silicon oxynitride.

According to some embodiments, the ions may include fluorine ions or boron ions.

According to some embodiments, the doping of the upper surface of the first barrier layer with the ions may be performed at an acceleration voltage of about 5 KeV to about 10 KeV.

According to some embodiments, the forming of the second substrate may include coating a material for forming the second substrate, on the upper surface of the first barrier layer, and heat-treating the material for forming the second substrate.

According to some embodiments, the heat-treating may be performed at temperature of about 410° C. to about 450° C.

According to some embodiments, the second substrate may include transparent polyimide.

According to some embodiments, an adhesive force of the first barrier layer may be 200 gf/inch or more.

According to some embodiments, the forming of the first thin-film transistor may include forming the first thin-film transistor including a first semiconductor layer including a silicon semiconductor and a first gate electrode insulated from the first semiconductor layer.

According to some embodiments, the method may further include forming an insulating layer on the first gate electrode, and forming a second thin-film transistor on the insulating layer, wherein the second thin-film transistor includes a second semiconductor layer and a second gate electrode insulated from the second semiconductor layer, and the second semiconductor layer includes an oxide semiconductor.

According to some embodiments, the method may further include forming a bottom metal layer between the second substrate and the buffer layer.

### BRIEF DESCRIPTION OF THE DRAWINGS

The above and other aspects, features, and characteristics of certain embodiments of the disclosure will be more apparent from the following description taken in conjunction with the accompanying drawings, in which:

FIGS. 1A and 1B are schematic perspective views of a display apparatus according to some embodiments;

FIGS. 2A and 2B are schematic cross-sectional views of a portion of an electronic apparatus according to some embodiments;

FIGS. 3A and 3B are schematic plan views of a display panel that may be included in a display apparatus according to some embodiments;

FIGS. 4 and 5 are schematic equivalent circuit diagrams of a light-emitting diode of a display apparatus according to some embodiments and a sub-pixel circuit electrically connected thereto;

FIG. 6 is a schematic cross-sectional view of a display apparatus according to some embodiments;

FIG. 7 is a cross-sectional view of a portion of a display apparatus according to some embodiments;

FIGS. 8 to 13 are schematic cross-sectional views showing a method of manufacturing a display apparatus according to some embodiments; and

FIG. 14 is a graph showing results of analyzing adhesive force of a first barrier layer according to some embodiments and a comparative example.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

In the present specification, “A and/or B” means A or B, or A and B. In the present specification, “at least one of A and B” means A or B, or A and B.

As used herein, when a wiring is referred to as “extending in a first direction or a second direction”, it means that the wiring not only extends in a straight line shape but also extends in a zigzag or in a curve in the first direction or the second direction.

As used herein, “on a plan view” means that an objective portion is viewed from above, and “on a cross-sectional view” means that a cross-section of an objective portion taken vertically is viewed from a lateral side. As used herein, “overlapping” includes overlapping “in a plan view” and “in a cross-sectional view.”

Hereinafter, aspects of some embodiments of the disclosure are described in more detail with reference to the accompanying drawings. When description is made with reference to the drawings, like reference numerals are used for like or corresponding elements.

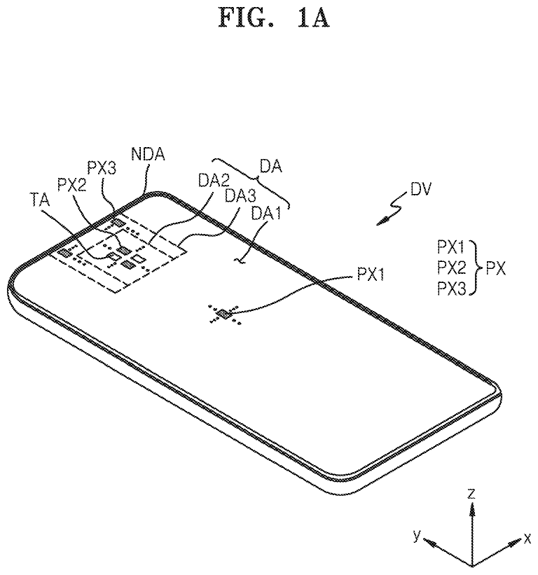

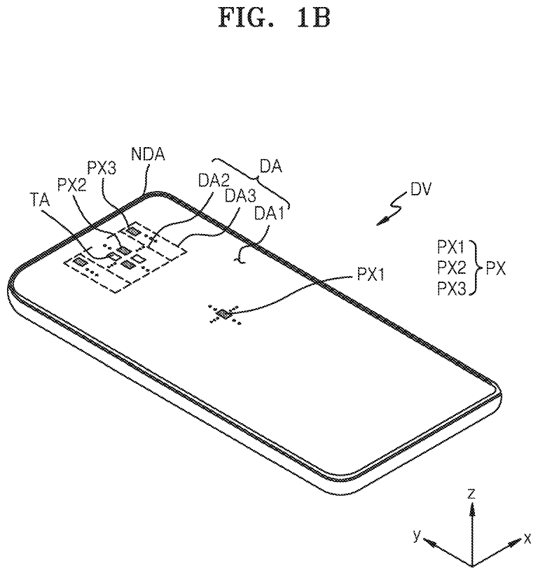

FIGS. 1A and 1B are schematic perspective views of a display apparatus DV according to some embodiments.

The display apparatus DV may be configured to display images. The display apparatus DV may include sub-pixels PX. The sub-pixel PX may be defined as a region through which a light-emitting element emits light. The sub-pixel PX may be provided in plurality in the display apparatus DV. The plurality of sub-pixels PX may each be configured to emit light, for example, red, green, blue, or white light. Each sub-pixel PX may be, for example, a red, green, or blue sub-pixel. According to some embodiments, the display apparatus DV may include a first sub-pixel PX1, a second sub-pixel PX2, and a third sub-pixel PX3.

The display apparatus DV may include a display area DA and a non-display area NDA outside (e.g., in a periphery or outside a footprint of) the display area DA in a plan view (e.g., a view perpendicular or normal with respect to a display surface of the display apparatus DV). The display area DA may include a first display area DA1, a second display area DA2, and a third display area DA3. The sub-pixels PX may be arranged in the first display area DA1, the second display area DA2, and the third display area DA3. The sub-pixels PX may not be arranged in the non-display area NDA. That is, the display area DA may be an area at which images are displayed, and the non-display area NDA may be an area at which images are not displayed.

The first display area DA1 may at least partially surround the second display area DA2 and the third display area DA3. According to some embodiments, the first display area DA1 may surround only a portion of the second display area DA2 and the third display area DA3. According to some embodiments, the first display area DA1 may surround the second display area DA2 and the third display area DA3 entirely. The first display area DA1 may include the first sub-pixel PX1. The first sub-pixel PX1 may be provided in plurality in the first display area DA1.

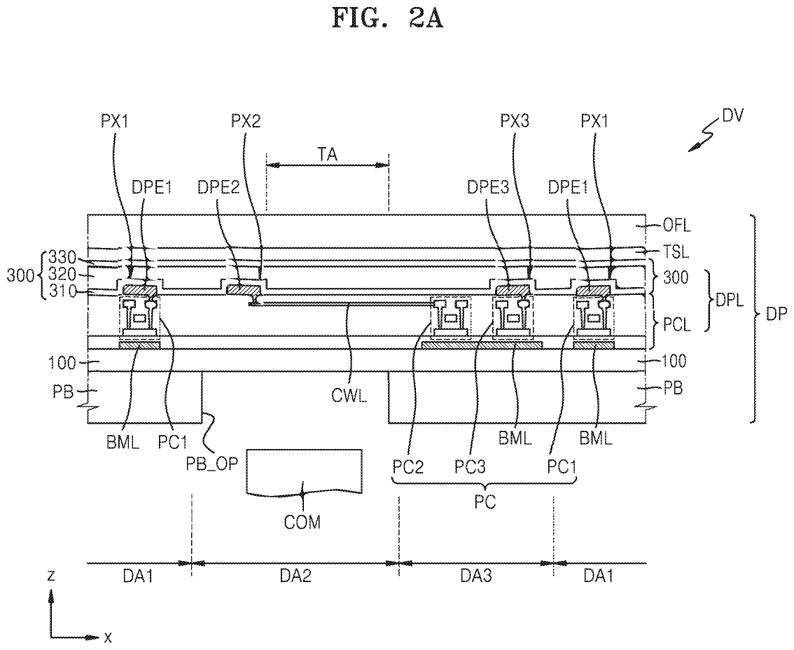

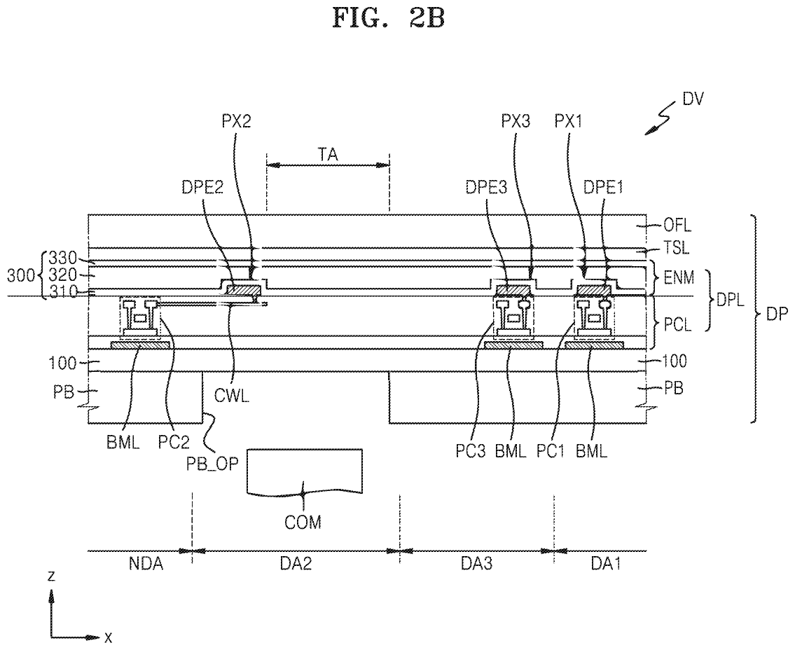

At least one of the second display area DA2 or the third display area DA3 may be a region overlapping a component. As an example, as described below with reference to FIG. 2A, a component COM (see FIG. 2A), which is an electronic element, may be arranged in the lower portion of the display apparatus DV to correspond to the second display area DA2. At least one of the second display area DA2 or the third display area DA3 may include a transmissive area TA through which signals (e.g., light and/or sound and the like) output from the component COM to the outside, or progressing toward the component COM from the outside, may pass or be transmitted.

At least one of the second display area DA2 or the third display area DA3 may be a region overlapping the component and simultaneously a region in which the sub-pixels PX are arranged. As an example, the second display area DA2 may be a region overlapping the component and simultaneously a region in which the sub-pixels PX are arranged. According to some embodiments, the second display area DA2 and the third display area DA3 may be regions overlapping the component and simultaneously regions in which the sub-pixels PX are arranged. According to some embodiments, the second sub-pixel PX2 may be arranged in the second display area DA2. The second sub-pixel PX2 may be provided in plurality in the second display area DA2. The third sub-pixel PX3 may be arranged in the third display area DA3. The third sub-pixel PX3 may be provided in plurality in the third display area DA3.

According to some embodiments, the resolution of an image displayed in at least one of the second display area DA2 or the third display area DA3 may be less than the resolution of an image displayed in the first display area DA1 (e.g., due to relatively lower density or higher spacing between pixels or sub-pixels compared to the first display area DA1). As an example, the resolution of the second display area DA2 may be about ½, ⅜, ⅓, ¼, 2/9, ⅛, 1/9, 1/16, or the like of the resolution of the first display area DA1. As an example, the resolution of the first display area DA1 may be 400 ppi or more, and the resolution of the second display area DA2 may be about 200 ppi or about 100 ppi. According to some embodiments, the resolution of one of the second display area DA2 and the third display area DA3 may be the same as the resolution of the first display area DA1.

At least one second display area DA2 may be provided in the display area DV. As an example, the display apparatus DV may include one second display area DA2 or a plurality of second display areas DA2. The third display area DA3 may be adjacent to the second display area DA2. The third display area DA3 may be arranged on one side of the second display area DA2. According to some embodiments, the third display area DA3 may be arranged on two opposite sides of the second display area DA2. According to some embodiments, the third display area DA3 may be omitted.

Although it is shown in FIGS. 1A and 1B that the second display area DA2 and the third display area DA3 are arranged on the upper center of the display apparatus DV, the second display area DA2 and the third display area DA3 may be arranged on the lower side, right side, or left side of the display apparatus DV.

According to some embodiments, at least one of the second display area DA2 or the third display area DA3 may have various shapes such as a circular shape, an elliptical shape, a polygon including a quadrangle, a star shape, a diamond shape, or the like in a plan view (e.g., an x-y plane). According to some embodiments, it is shown in FIGS. 1A and 1B that the second display area DA2 and the third display area DA3 each have a quadrangular shape.

The display apparatus DV of FIGS. 1A and 1B may be used in the following electronic apparatus. As an example, the display apparatus DV according to some embodiments may be used in portable electronic apparatuses such as mobile phones, smartphones, tablet personal computers, mobile communication terminals, electronic organizers, electronic books, portable multimedia players (PMPs), navigations, and ultra mobile personal computers (UMPCs), and the like.

In addition, the display apparatus DV according to some embodiments may be used in wearable electronic apparatuses including smartwatches, watchphones, glasses-type displays, and head-mounted displays (HMDs). In addition, the display apparatus DV according to some embodiments may be used as instrument panels for automobiles, center fascias for automobiles, or center information displays (CIDs) arranged on a dashboard, room mirror displays that replace side mirrors of automobiles, and displays arranged on the backside of front seats as an entertainment for back seats of automobiles.

FIGS. 2A and 2B are schematic cross-sectional views of the electronic apparatus according to some embodiments.

Referring to FIGS. 2A and 2B, the electronic apparatus may include the display apparatus DV and the component COM overlapping the display apparatus DV. In addition, the electronic apparatus may further include a housing and a cover window, wherein the housing receives the display apparatus DV, and the cover window is located on the display apparatus DV and protects the display apparatus DV.

The display apparatus DV may include a display panel DP. In addition, the display apparatus DV may further include an input sensor and a driving circuit, wherein the input sensor senses an external input. The display panel DP may include a substrate 100, a display layer DPL, a touchscreen layer TSL, an optical functional layer OFL, and a panel protection member PB, the display layer DPL, the touchscreen layer TSL, and the optical functional layer OFL being on the substrate 100, and the panel protection member PB being under the substrate 100.

The component COM may be an electronic element that uses light or sound. As an example, the electronic element may be a sensor that measures a distance such as a proximity sensor, a sensor that recognizes a portion of a user's body (e.g., a fingerprint, an iris, a face and the like), a small lamp that outputs light, or an image sensor (e.g., a camera) that captures images. The electronic element that uses light may use light in various wavelength bands such as visible light, infrared light, ultraviolet light and the like. The electronic element that uses sound may use ultrasonic waves or sound in different frequency bands. According to some embodiments, the component COM may include sub-components such as a light-emitter and a light-receiver. The light-emitter and the light-receiver may have a structure integrated in one body, or a pair of the light-emitter and the light-receiver that are physically separated may constitute one component COM.

The display panel DP may include the first display area DA1, the second display area DA2, and the third display area DA3. In other words, the first display area DA1, the second display area DA2, and the third display area DA3 may be defined in the substrate 100 and a multi-layer on the substrate 100. Hereinafter, description is made on the assumption that the substrate 100 includes the first display area DA1, the second display area DA2, and the third display area DA3.

The display layer DPL may include a pixel circuit layer PCL, a light-emitting diode layer, and an encapsulation member ENM, wherein the pixel circuit layer PCL includes a sub-pixel circuit PC, the light-emitting diode layer includes a light-emitting diode, and the encapsulation member ENM includes a thin-film encapsulation layer 300 or an encapsulation substrate.

An insulating layer may be located between the substrate 100 and the display layer DPL, and inside the display layer DPL. The light-emitting diode may be, for example, an organic light-emitting diode. Although a light-emitting diode is described as including an organic light-emitting diode in the description below, the embodiments according to the present disclosure are not limited thereto. According to some embodiments, the light-emitting diode may be a light-emitting diode including an inorganic material, or a quantum-dot light-emitting diode including quantum dots. As an example, an emission layer of the light-emitting diode may include an organic material, an inorganic material, quantum dots, an organic material and quantum dots, or an inorganic material and quantum dots.

The pixel circuit layer PCL may be located on the substrate 100. The pixel circuit layer PCL may include the sub-pixel circuit PC, a connection line CWL, and an insulating layer. The sub-pixel circuit PC may include a first sub-pixel circuit PC1, a second sub-pixel circuit PC2, and a third sub-pixel circuit PC3. The first sub-pixel circuit PC1 may be arranged in the first display area DA1. The second sub-pixel circuit PC2 and the third sub-pixel circuit PC3 may be arranged in the third display area DA3. The sub-pixel circuit PC may not be arranged in the second display area DA2.

According to some embodiments, a first light-emitting diode DPE1 and the first sub-pixel circuit PC1 connected thereto may be arranged in the first display area DA1 of the substrate 100. The first sub-pixel circuit PC1 may include at least one thin-film transistor and be configured to control an operation of the first light-emitting diode DPE1. The first sub-pixel PX1 may be implemented by light emission of the first light-emitting diode DPE1.

According to some embodiments, a second display element DPE2 may be arranged in the second display area DA2 of the substrate 100 and may implement the second sub-pixel PX2. According to some embodiments, as shown in FIG. 2A, the second sub-pixel circuit PC2 configured to drive the second light-emitting diode DPE2 may not be arranged in the second display area DA2, but may be arranged in the third display area DA3 between the first display area DA1 and the second display area DA2. According to some embodiments, as shown in FIG. 2B, the second sub-pixel circuit PC2 configured to drive the second light-emitting diode DPE2, may not be arranged in the third display area DA3, but may be arranged in the non-display area NDA. That is, the second sub-pixel circuit PC2 may be arranged not to overlap the second light-emitting diode DPE2.

The second sub-pixel circuit PC2 may include at least one thin-film transistor, and be electrically connected to the second light-emitting diode DPE2 by the connection line CWL. The connection line CWL may include a transparent conductive material. The second sub-pixel circuit PC2 may be configured to control an operation of the second light-emitting diode DPE2. The second sub-pixel PX2 may be implemented by light emission of the second light-emitting diode DPE2.

A region of the second display area DA2 in which the second sub-pixel PX2 is not arranged may be defined as the transmissive area TA. The transmissive area TA may be a region through which light/signal emitted from the component COM, or light/signal incident to the component COM passes, the component COM being arranged to correspond to the second display area DA2.

The connection line CWL connecting the second sub-pixel circuit PC2 to the second light-emitting diode DPE2 may be arranged in the transmissive area TA. Because the connection line CWL may include a transparent conductive material having a high transmittance, even though the connection line CWL is arranged in the transmissive area TA, a transmittance of the transmissive area TA may be secured.

According to some embodiments, a third light-emitting diode DPE3 and the third sub-pixel circuit PC3 connected thereto, may be arranged in the third display area DA3 of the substrate 100 and may implement the third sub-pixel PX3. The second sub-pixel circuit PC2 and the third sub-pixel circuit PC3 arranged in the third display area DA3, may be adjacent to each other and alternately arranged.

As shown in FIGS. 2A and 2B, the light-emitting diode layer may be covered by the thin-film encapsulation layer 300 or the encapsulation substrate. According to some embodiments, the thin-film encapsulation layer 300 may include at least one inorganic encapsulation layer and at least one organic encapsulation layer. As an example, the thin-film encapsulation layer 300 may include a first inorganic encapsulation layer 310, a second inorganic encapsulation layer 330, and an organic encapsulation layer 320.

The touchscreen layer TSL may obtain coordinate information corresponding to an external input, for example, a touch event. The touchscreen layer TSL may include a touch electrode and touch lines connected to the touch electrode. The touchscreen layer TSL may sense an external input by using a self-capacitance method or a mutual capacitance method.

The touchscreen layer TSL may be formed on the thin-film encapsulation layer 300. Alternatively, the touchscreen layer TSL may be separately formed on a touch substrate and then coupled on the thin-film encapsulation layer 300 through an adhesive layer such as an optically clear adhesive OCA. According to some embodiments, the touchscreen layer TSL may be directly formed on the encapsulation layer 300. In this case, the adhesive layer may not be located between the touchscreen layer TSL and the encapsulation layer 300.

The optical functional layer OFL may include an anti-reflection layer. The anti-reflection layer may reduce reflectivity of light (external light) incident toward the display apparatus DV from the outside. According to some embodiments, the optical functional layer OFL may be a polarization film. According to some embodiments, the optical functional layer OFL may include an opening corresponding to the transmissive area TA. Accordingly, a light transmittance of the transmissive area TA may be remarkably improved. A transparent material such as an optically clear resin (OCR) may fill the opening. According to some embodiments, the optical functional layer OFL may be a filter plate including a black matrix and color filters.

The panel protection member PB may be located under the substrate 100. The panel protection member PB may support and protect the substrate 100. The panel protection member PB may have an opening PB_OP overlapping the second display area DA2. According to some embodiments, the opening PB_OP of the panel protection member PB may overlap the second display area DA2 and the third display area DA3. According to some embodiments, the panel protection member PB may include polyethylene terephthalate or polyimide.

The cover window may be located on the display apparatus DV. The cover window may be configured to protect the display apparatus DV, for example, the display panel DP. The cover window may include at least one of glass, sapphire, or plastic. The cover window may be, for example, ultra-thin glass (UTG) or colorless polyimide (CPI).

The component COM may be arranged below the display apparatus DV. According to some embodiments, the component COM may be arranged opposite the cover window with the display panel DP therebetween. According to some embodiments, the component COM may overlap the second display area DA2 and/or the third display area DA3.

As shown in FIGS. 2A and 2B, a bottom metal layer BML may be located below the sub-pixel circuit PC. The bottom metal layer BML may overlap the sub-pixel circuit PC to protect the sub-pixel circuit PC. According to some embodiments, the bottom metal layer BML may be arranged to overlap the second and/or third sub-pixel circuits PC2 and PC3 between the substrate 100 corresponding to the third display area DA3, and the second sub-pixel circuit PC2 and/or the third sub-pixel circuit PC3. The bottom metal layer BML may also be located below the first sub-pixel circuit PC1 of the first display area DA1. According to some embodiments, the bottom metal layer BML may be omitted.

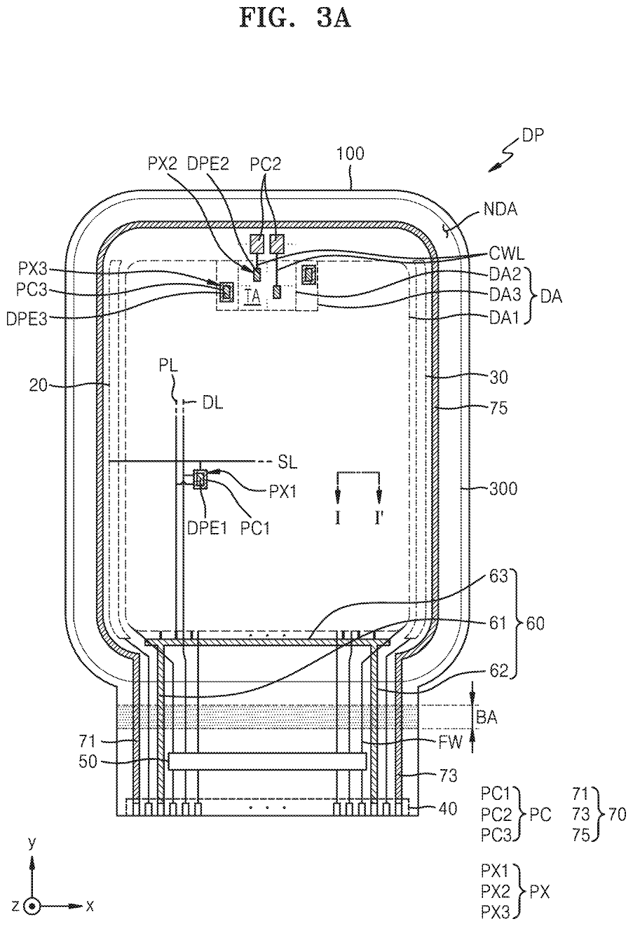

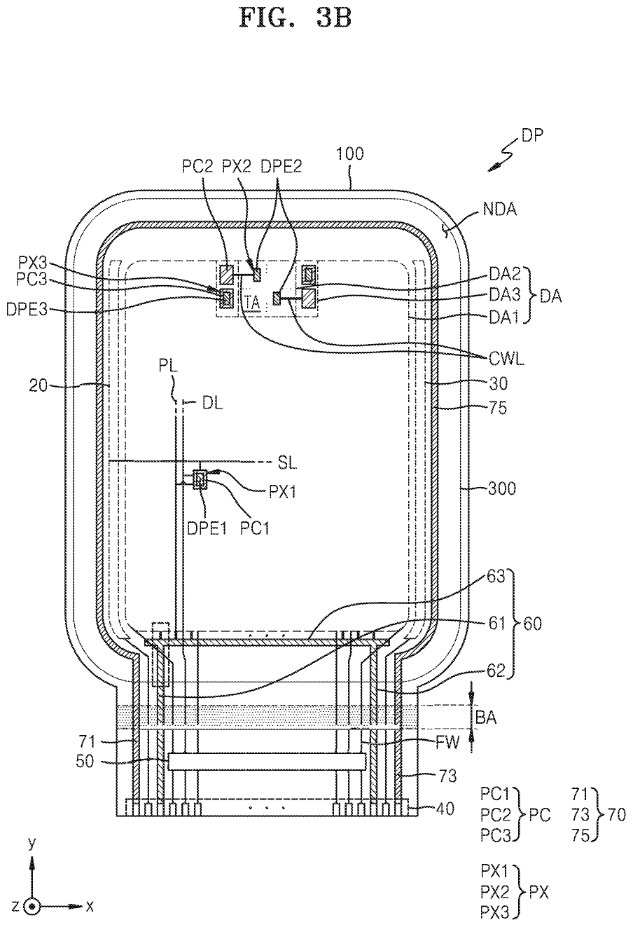

FIGS. 3A and 3B are schematic plan views of the display panel DP that may be included in the display apparatus DV according to some embodiments.

Referring to FIGS. 3A and 3B, the display panel DP may include first and second drivers 20 and 30, a terminal portion 40, a data driver 50, and a power supply line located on the substrate 100. The power supply line may include a driving voltage supply line 60 and a common voltage supply line 70.

The substrate 100 may include the display area DA and the non-display area NDA outside the display area DA. A portion of the non-display area NDA may extend in one side (e.g., a −y direction). The terminal portion 40, the data driver 50, the driving voltage supply line 60, a fan-out wiring FW, and the like may be arranged in the non-display area NDA that extends.

The substrate 100 may include a bending area BA in which a portion of the non-display area NDA that extends is bendable. When the non-display area NDA, which extends with respect to the bending area BA, is folded, the non-display area NDA that extends may partially overlap the display area DA. Through this structure, the non-display area NDA that extends may not be viewed by a user, or even though the non-display area NDA that extends is viewed by a user, a viewed area may be relatively reduced.

A plurality of sub-pixels PX may be arranged in the display area DA. The sub-pixel circuits PC driving the sub-pixels PX in the display area DA may each be connected to a signal line or a voltage line configured to control turning-on/off, brightness, and the like of a light-emitting diode. As an example, FIGS. 3A and 3B show a scan line SL extending in a first direction (e.g., an x direction), a data line DL extending in a second direction (e.g., a y direction), and a driving voltage line PL as a voltage line.

A plurality of first sub-pixels PX1 may be arranged in the first display area DA1. Each of the first sub-pixels PX1 may include a light-emitting diode such as an organic light-emitting diode. A plurality of first sub-pixel circuits PC1 respectively driving the plurality of first sub-pixels PX1 may be arranged in the first display area DA1, and each first sub-pixel circuit PC1 may be arranged to overlap each first sub-pixel PX1 corresponding thereto.

As described above, the second display area DA2 and the third display area DA3 may be located on one side of the first display area DA1, or surrounded by the first display area DA1. The third display area DA3 may at least partially surround the second display area DA2. A plurality of second sub-pixels PX2 may be arranged in the second display area DA2, and a plurality of third sub-pixels PX3 may be arranged in the third display area DA3. Each of the second sub-pixels PX2 and the third sub-pixels PX3 may include a light-emitting diode such as an organic light-emitting diode.

The second sub-pixel PX2 may be implemented in the second display area DA2, and the third sub-pixel PX3 may be implemented in the third display area DA3. That is, it may be understood that the second sub-pixel PX2 is configured to substantially emit light in the second display area DA2, and the third sub-pixel PX3 is configured to substantially emit light in the third display area DA3.

Referring to FIG. 3A, because a second light-emitting diode DPE2 implementing the second sub-pixel PX2 is arranged in the second display area DA2, and the second sub-pixel circuit PC2 is arranged in the third display area DA3, the second light-emitting diode DPE2 may be connected to the second sub-pixel circuit PC2 by the connection line CWL. According to some embodiments, referring to FIG. 3B, because a second light-emitting diode DPE2 implementing the second sub-pixel PX2 is arranged in the second display area DA2, and the second sub-pixel circuit PC2 is arranged in the non-display area NDA, the second light-emitting diode DPE2 may be connected to the second sub-pixel circuit PC2 by the connection line CWL.

As described above, in the case where the second sub-pixel circuit PC2 may be arranged in the third display area DA3 or the non-display area NDA, and the second light-emitting diode DPE2 is arranged in the third display area DA3, the area of the transmissive area TA may be increased while the resolution of the second display area DA2 is maintained.

The first scan driver 20 and the second scan driver 30 may be configured to generate and transfer a scan signal to each sub-pixel circuit PC through the scan line SL. According to some embodiments, one of the first scan driver 20 and the second scan driver 30 may be configured to apply an emission control signal to each sub-pixel circuit PC through an emission control line. According to some embodiments, though a structure in which the first and second scan drivers 20 and 30 are respectively arranged on two opposite sides of the display area DA, the scan drivers may be arranged on only one side of the display area DA according to some embodiments. The second scan driver 30 may be arranged to symmetrical to the first scan driver 20 with respect to the display area DA.

The data driver 50 may be configured to generate and transfer a data signal to each sub-pixel circuit PC through the data line DL. Though it is shown in FIGS. 3A and 3B that the data driver 50 is located on the substrate 100, the data driver 50 may be provided on a flexible printed circuit board connected to the terminal portion 40 according to some embodiments.

The terminal portion 40 is arranged on one end of the substrate 100 and includes a plurality of terminals. The terminal portion 40 may be exposed without being covered by an insulating layer, and electrically connected to a controller such as a flexible printed circuit board or an integrated circuit (IC) chip. Control signals of the controller may be respectively provided to the first and second drivers 20 and 30, the terminal portion 40, the data driver 50, the driving voltage supply line 60, and the common voltage supply line 70 through the terminal portion 40.

The driving voltage supply line 60 may be configured to provide a driving voltage ELVDD to each sub-pixel PX. According to some embodiments, the driving voltage supply line 60 may include a first driving voltage supply line 61, a second driving voltage supply line 62, and a third driving voltage supply line 63. The third driving voltage supply line 63 may extend in the first direction (e.g., the x direction), and the first and second driving voltage lines 61 and 62 may extend in the second direction (e.g., the y direction). According to some embodiments, the first driving voltage supply line 61, the second driving voltage supply line 62, and the third driving voltage supply line 63 may be integrally provided.

The driving voltage supply line 60 may be connected to a plurality of driving voltage lines PL. As an example, the third driving voltage supply line 63 may be connected to the driving voltage line PL crossing the display area DA in the second direction (e.g., the y direction).

The common voltage supply line 70 may be configured to provide a common voltage ELVSS to each sub-pixel PX. According to some embodiments, the common voltage supply line 70 may include a first common voltage supply line 71 and a second common voltage supply line 73. The first common voltage supply line 71 and the second common voltage supply line 73 may extend in the second direction (e.g., the y direction) and be apart from each other in the first direction (e.g., the x direction) crossing the second direction (e.g., the y direction). The first common voltage supply line 71 and the second common voltage supply line 73 may be connected to each other by a body portion 75 extending along the edge of the display area DA. According to some embodiments, the first common voltage supply line 71, the second common voltage supply line 73, and the body portion 75 may be integrally formed.

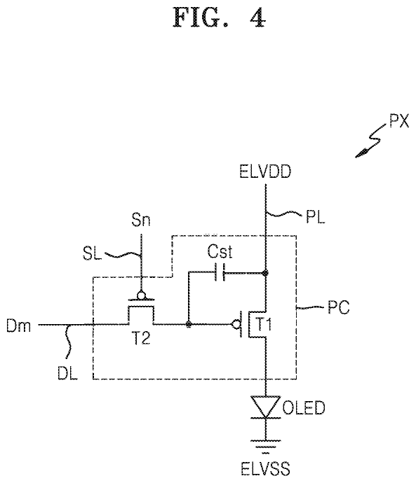

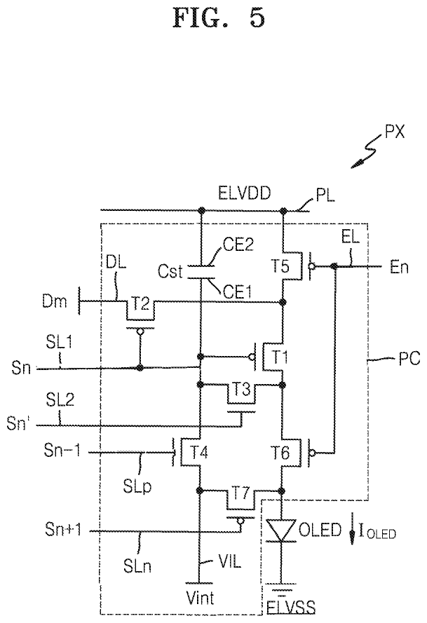

FIGS. 4 and 5 are equivalent circuit diagrams of a pixel of the display apparatus according to some embodiments.

Referring to FIG. 4, each sub-pixel PX may include the sub-pixel circuit PC and the organic light-emitting diode OLED connected to the pixel circuit PC, wherein the sub-pixel circuit PC is connected to the scan line SL and the data line DL. The sub-pixel circuit PC shown in FIG. 4 may correspond to each of the first sub-pixel circuit PC1, the second sub-pixel circuit PC2, and the third sub-pixel circuit PC3 described with reference to FIGS. 3A and 3B. The organic light-emitting diode OLED shown in FIG. 4 may correspond to each of the first light-emitting diode DPE1, the second light-emitting diode DPE2, and the third light-emitting diode DPE3 described with reference to FIGS. 3A and 3B.

The sub-pixel circuit PC may include a driving thin-film transistor T1, a switching thin-film transistor T2, and a storage capacitor Cst. The switching thin-film transistor T2 may be connected to the scan line SL and the data line DL, and configured to transfer a data signal Dm to the driving thin-film transistor T1 according to a scan signal Sn, wherein the data signal Dm is input through the data line DL, and the scan signal Sn is input through the scan line SL.

The storage capacitor Cst may be connected to the switching thin-film transistor T2 and a driving voltage line PL and configured to store a voltage corresponding to a difference between a voltage transferred from the switching thin-film transistor T2 and the driving voltage ELVDD supplied to the driving voltage line PL.

The driving thin-film transistor T1 may be connected to the driving voltage line PL and the storage capacitor Cst and configured to control a driving current according to the voltage stored in the storage capacitor Cst, the driving current flowing from the driving voltage line PL to the organic light-emitting diode OLED. The organic light-emitting diode OLED may be configured to emit light having a preset brightness corresponding to the driving current.

Although it is described with reference to FIG. 4 that the sub-pixel circuit PC includes two thin-film transistors and one storage capacitor, the embodiments according to the present disclosure are not limited thereto. As an example, the sub-pixel circuit PC may include three or more thin-film transistors and/or two or more storage capacitors. According to some embodiments, the sub-pixel circuit PC may include seven transistors and one storage capacitor. This is described with reference to FIG. 5. Additionally, according to some embodiments, the sub-pixel circuit PC may include additional components or fewer components than what is illustrated and described with respect to FIGS. 4 and 5 without departing from the spirit and scope of embodiments according to the present disclosure.

Referring to FIG. 5, a sub-pixel PX may include the sub-pixel circuit PC and the organic light-emitting diode OLED electrically connected to the sub-pixel circuit PC.

According to some embodiments, as shown in FIG. 5, the sub-pixel circuit PC may include a plurality of thin-film transistors T1, T2, T3, T4, T5, T6, and T7 and the storage capacitor Cst. The thin-film transistors T1, T2, T3, T4, T5, T6, and T7 and the storage capacitor Cst may be connected to signal lines SL1, SL2, SLp, SLn, EL, and DL, an initialization voltage line VIL, and the driving voltage line PL. According to some embodiments, at least one of the signal lines SL1, SL2, SLp, SLn, EL, or DL, the initialization voltage line VIL, and/or the driving voltage line PL may be shared by the sub-pixels PX adjacent to each other.

The thin-film transistors may include a driving thin-film transistor T1, a switching thin-film transistor T2, a compensation thin-film transistor T3, a first initialization thin-film transistor T4, an operation control thin-film transistor T5, an emission control thin-film transistor T6, and a second initialization thin-film transistor T7.

Some of the plurality of thin-film transistors T1, T2, T3, T4, T5, T6, and T7 may be n-channel metal-oxide semiconductor (NMOS) field-effect transistors (n-channel MOSFETs), and the rest may be p-channel metal-oxide semiconductor (PMOS) field-effect transistors (p-channel MOSFETs). As an example, among the plurality of thin-film transistors T1, T2, T3, T4, T5, T6, and T7, the compensation thin-film transistor T3 and the first initialization thin-film transistor T4 may be n-channel MOSFETs (NMOSs), and the rest may be p-channel MOSFETs (PMOSs). Alternatively, among the plurality of thin-film transistors T1, T2, T3, T4, T5, T6, and T7, the compensation thin-film transistor T3, the first initialization thin-film transistor T4, and the second initialization thin-film transistor T7 may be n-channel MOSFETs (NMOSs), and the rest may be p-channel MOSFETs (PMOSs). Alternatively, all of the plurality of thin-film transistors T1, T2, T3, T4, T5, T6, and T7 may be NMOSs or PMOSs.

Hereinafter, for convenience of description, the case where the compensation thin-film transistor T3 and the first initialization thin-film transistor T4 are NMOSs including an oxide semiconductor, and the rest are PMOSs, is described.

The signal lines may include the first scan line SL1, the second scan line SL2, the previous scan line SLp, the emission control line EL, the next scan line SLn, and the data line DL, wherein the first scan line SL1 is configured to transfer a first scan signal Sn, the second scan line SL2 is configured to transfer a second scan signal Sn′, the previous scan line SLp is configured to transfer a previous scan signal Sn−1 to the first initialization thin-film transistor T4, the emission control line EL is configured to transfer an emission control signal En to the operation control thin-film transistor T5 and the emission control thin-film transistor T6, the next scan line SLn is configured to transfer a next scan signal Sn+1 to the second initialization thin-film transistor T7, and the data line DL crosses the first scan line SL1 and is configured to transfer a data signal Dm.

The driving voltage line PL may be configured to transfer the driving voltage ELVDD to the driving thin-film transistor T1, and the initialization voltage line VIL may be configured to transfer an initialization voltage Vint initializing the driving thin-film transistor T1 and a sub-pixel electrode.

A driving gate electrode of the driving thin-film transistor T1 may be connected to the storage capacitor Cst, a driving source region of the driving thin-film transistor T1 may be connected to the driving voltage line PL through the operation control thin-film transistor T5, and a drain region of the driving thin-film transistor T1 may be electrically connected to a sub-pixel electrode of the organic light-emitting diode OLED through the emission control thin-film transistor T6. The driving thin-film transistor T1 may be configured to receive a data signal Dm and supply a driving current I_{OLED} to the organic light-emitting diode OLED according to a switching operation of the switching thin-film transistor T2.

A switching gate electrode of the switching thin-film transistor T2 is connected to the first scan line SL1, a switching source region of the switching thin-film transistor T2 is connected to the data line DL, and a switching drain region of the switching thin-film transistor T2 is connected to the driving source region of the driving thin-film transistor T1 and connected to the driving voltage line PL through the operation control thin-film transistor T5. The switching thin-film transistor T2 may be turned on according to a first scan signal Sn transferred through the first scan line SL1 and may perform a switching operation of transferring a data signal Dm to the driving source region of the driving thin-film transistor T1, wherein the data signal Dm is transferred through the data line DL.

A compensation gate electrode of the compensation thin-film transistor T3 is connected to the second scan line SL2. A compensation drain region of the compensation thin-film transistor T3 is connected to the driving drain region of the driving thin-film transistor T1 and connected to the pixel electrode of the organic light-emitting diode OLED through the emission control thin-film transistor T6. A compensation source region of the compensation thin-film transistor T3 is connected to a first capacitor electrode CE1 of the storage capacitor Cst and the driving gate electrode of the driving thin-film transistor T1. In addition, the compensation source region is connected to a first initialization drain region of the first initialization thin-film transistor T4.

The compensation thin-film transistor T3 is turned on according to a second scan signal Sn′ and may diode-connect the driving thin-film transistor T1 by electrically connecting the driving gate electrode to the driving drain region of the driving thin-film transistor T1, wherein the second scan signal Sn′ is transferred through the second scan line SL2.

A first initialization gate electrode of the first initialization transistor T4 is connected to the previous scan line SLp. A first initialization source region of the first initialization thin-film transistor T4 is connected to a second initialization source region of the second initialization thin-film transistor T7 and the initialization voltage line VIL. A first initialization drain region of the first initialization thin-film transistor T4 is connected to the first capacitor electrode CE1 of the storage capacitor Cst, the compensation source region of the compensation thin-film transistor T3, and the driving gate electrode of the driving thin-film transistor T1. That is, the first initialization thin-film transistor T4 may be turned on according to a previous scan signal Sn−1 received through the previous scan line SLp and may perform an initialization operation of initializing the voltage of the driving gate electrode of the driving thin-film transistor T1 by transferring the initialization voltage Vint to the driving gate electrode of the driving thin-film transistor T1.

An operation control gate electrode of the operation control thin-film transistor T5 is connected to the emission control line EL, an operation control source region of the operation control thin-film transistor T5 is connected to the driving voltage line PL, and an operation control drain region of the operation control thin-film transistor T5 is connected to the driving source region of the driving thin-film transistor T1 and the switching drain region of the switching thin-film transistor T2.

An emission control gate electrode of the emission control thin-film transistor T6 is connected to the emission control line EL, an emission control source region of the emission control thin-film transistor T6 is connected to the driving drain region of the driving thin-film transistor T1 and the compensation drain region of the compensation thin-film transistor T3, and an emission control drain region of the emission control thin-film transistor T6 is electrically connected to a second initialization drain region of the second initialization thin-film transistor T7 and the pixel electrode of the organic light-emitting diode OLED.

The operation control thin-film transistor T5 and the emission control thin-film transistor T6 may be simultaneously (or concurrently) turned on according to an emission control signal En transferred through the emission control line EL, the driving voltage ELVDD is transferred to the organic light-emitting diode OLED, and the driving current I_{OLED} flows through the organic light-emitting diode OLED.

A second initialization gate electrode of the second initialization thin-film transistor T7 is connected to the next scan line SLn, a second initialization drain region of the second initialization thin-film transistor T7 is connected to the emission control drain region of the emission control thin-film transistor T6 and the pixel electrode of the organic light-emitting diode OLED, and a second initialization source region of the second initialization thin-film transistor T7 is connected to the first initialization source region of the first initialization thin-film transistor T4 and the initialization voltage line VIL. The second thin-film transistor T7 is turned on according to a next scan signal Sn+1 transferred through the next scan line SLn and initializes the pixel electrode of the organic light-emitting diode OLED.

As shown in FIG. 5, the second initialization thin-film transistor T7 may be connected to the next scan line SLn. According to some embodiments, the second initialization thin-film transistor T7 may be connected to the emission control line EL and driven according to an emission control signal En. The positions of source regions and drain regions may be exchanged depending on the type (a p-type or an n-type) of the transistor.

The storage capacitor Cst may include the first capacitor electrode CE1 and a second capacitor electrode CE2. The first capacitor electrode CE1 of the storage capacitor Cst is connected to the driving gate electrode of the driving thin-film transistor T1, and the second capacitor electrode CE2 of the storage capacitor Cst is connected to the driving voltage line PL. The storage capacitor Cst may be configured to store charge corresponding to a difference between a voltage of the driving gate of the driving thin-film transistor T1 and the driving voltage ELVDD.

A specific operation of each sub-pixel PX according to some embodiments is described below.

When a previous scan signal Sn−1 is supplied through the previous scan line SLp during an initialization period, the first initialization thin-film transistor T4 is turned on according to the previous scan signal Sn−1, and the driving thin-film transistor T1 may be initialized by the initialization voltage Vint supplied from the initialization voltage line VIL.

When a first scan signal Sn and a second scan signal Sn′ are supplied through the first scan line SL1 and the second scan line SL2 during a data programming period, the switching thin-film transistor T2 and the compensation thin-film transistor T3 are turned on according to the first scan signal Sn and the second scan signal Sn′. In this case, the driving thin-film transistor T1 is diode-connected and forward-biased by the compensation thin-film transistor T3 that is turned on.

Then, a compensation voltage Dm+Vth (Vth has a (−) value) is applied to the driving gate electrode of the driving thin-film transistor T1, wherein the compensation voltage Dm+Vth is a voltage reduced by a threshold voltage Vth of the driving thin-film transistor T1 from a data signal Dm supplied from the data line DL.

The driving voltage ELVDD and the compensation voltage Dm+Vth are respectively applied to two opposite ends of the storage capacitor Cst, and charge corresponding to a difference between voltages of the two opposite ends is stored in the storage capacitor Cst.

During an emission period, the operation control thin-film transistor T5 and the emission control thin-film transistor T6 are turned on according to an emission control signal En supplied from the emission control line EL. The driving current I_{OLED} corresponding to a voltage difference between the driving gate voltage of the driving thin-film transistor T1 and the driving voltage ELVDD occurs, and the driving current I_{OLED} is supplied to the organic light-emitting diode OLED through the emission control thin-film transistor T6.

According to some embodiments, at least one of the plurality of thin-film transistors T1, T2, T3, T4, T5, T6, or T7 may include an oxide semiconductor layer, and the rest may include a silicon semiconductor layer.

For example, the driving thin-film transistor T1 directly influencing the brightness of the display apparatus may be configured to include a semiconductor layer including polycrystalline silicon having high reliability, and thus, a high-resolution display apparatus may be implemented through this configuration.

Because an oxide semiconductor has high carrier mobility and a low leakage current, a voltage drop is not large even when a driving time is long. That is, because a color change of an image according to a voltage drop is not large even while the display apparatus is driven in low frequencies, the display apparatus may be driven in low frequencies.

Because the oxide semiconductor has an advantage of a low leakage current, at least one of the compensation thin-film transistor T3, the first initialization thin-film transistor T4, or the second initialization thin-film transistor T7 connected to the driving gate electrode of the driving thin-film transistor T1 may include an oxide semiconductor, and thus, a leakage current that may flow to the driving gate electrode may be prevented, and simultaneously (or concurrently), power consumption may be reduced.

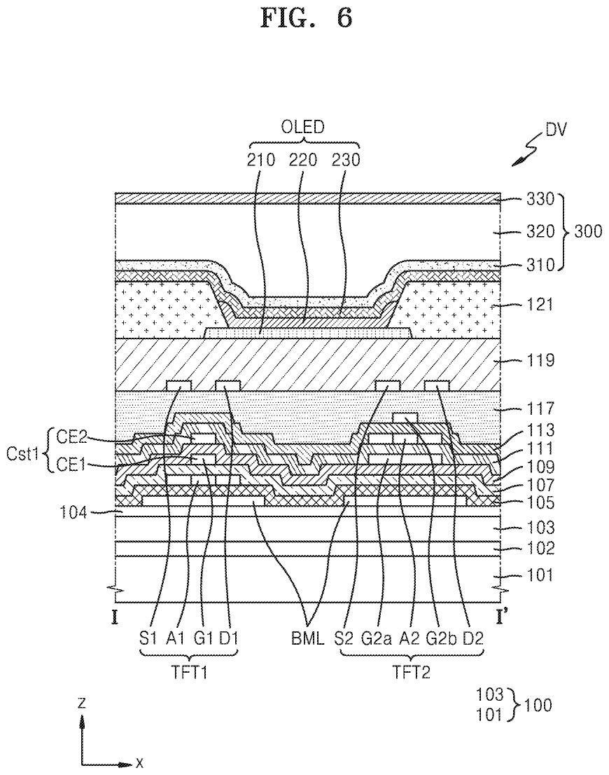

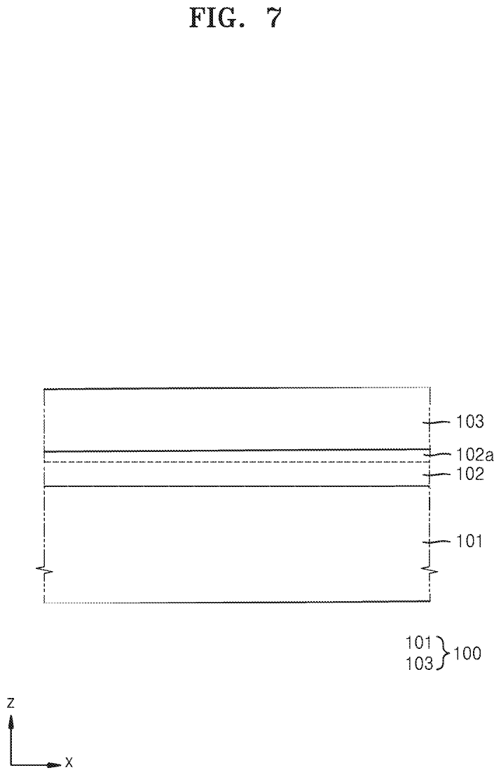

FIG. 6 is a schematic cross-sectional view of a portion of the display apparatus, taken along the line I-I′ of FIG. 3A, according to some embodiments. FIG. 7 is a schematic cross-sectional view of a portion of FIG. 6 and an extracted enlarged view of a portion of a first substrate 101, a first barrier layer 102, and a second substrate 103 of FIG. 6.

Referring to FIGS. 6 and 7, the display apparatus DV includes the substrate 100 and various elements located on the substrate 100. The substrate 100 may be flexible or bendable. The substrate 100 may include polymer resin, for example, polyethersulfone, polyacrylate, polyetherimide, polyethylene naphthalate, polyethylene terephthalate, polyphenylene sulfide, polyarylate, polycarbonate, or cellulose acetate propionate.

The substrate 100 may have various structures and have a multi-layered structure as shown in FIG. 1. The substrate 100 may include the first substrate 101 and the second substrate 103. In the case where the display apparatus includes one substrate (e.g., a single polyimide substrate), the substrate may be damaged during a process of separating the substrate from a glass substrate in the manufacturing process. According to some embodiments, in the case where the substrate 100 includes the first substrate 101 and the second substrate 103, mechanical properties of the substrate 100 may be improved. The first barrier layer 102 may be located between the first substrate 101 and the second substrate 103.

The first substrate 101 and the second substrate 103 may include polymer resin. According to some embodiments, the first substrate 101 and the second substrate 103 may include the same material. As an example, both the first substrate 101 and the second substrate 103 may include polyimide. According to some embodiments, the first substrate 101 and the second substrate 103 may include different materials.

As described with reference to FIGS. 1A to 3B, in the case where the component COM is located below the substrate 100 (e.g., the second display area DA2 (see FIG. 2A) of the substrate 100) of the display apparatus DV, a high transmittance of the substrate 100 may be required. According to some embodiments, the first substrate 101 and the second substrate 103 may include polymer resin. As an example, each of the first substrate 101 and the second substrate 103 may include transparent polyimide, not yellow polyimide. Transparent polyimide may be different from yellow polyimide in physical properties such as film density, thermal expansion coefficient, and crystallinity. As an example, transparent polyimide may be less than yellow polyimide in film density and crystallinity and greater than yellow polyimide in thermal expansion coefficient.

The first barrier layer 102 may be located between the first substrate 101 and the second substrate 103. The first barrier layer 102 may include an inorganic insulating material such as silicon nitride, silicon oxynitride, and silicon oxide, and include a single-layered structure or a multi-layered structure including the above materials.

The first barrier layer 102 may prevent or reduce instances of impurities such as contaminants, external moisture, or oxygen passing through the first substrate 101 and penetrating the second substrate 103. Through this, impurities introduced from the outside may be prevented from penetrating elements on the upper portion of the substrate 100 and causing defects.

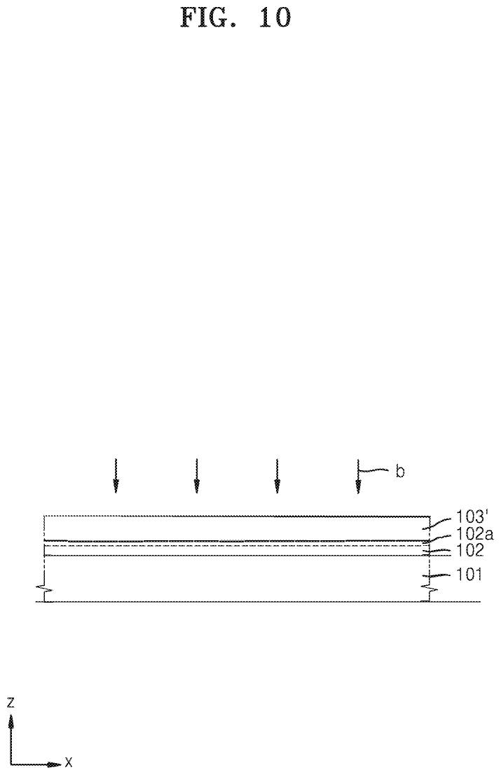

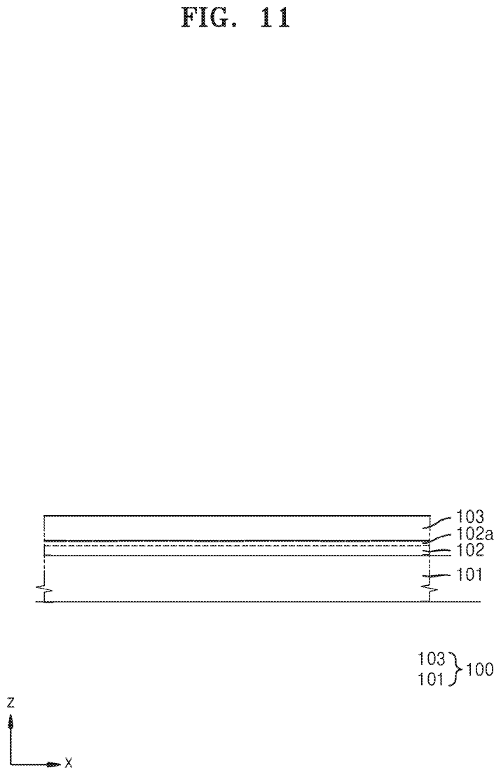

Referring to FIGS. 6 and 7, a portion including the upper surface (e.g., a surface in a +z direction) of the first barrier layer 102 may be ion-doped. A portion including the entire upper surface of the first barrier layer 102 may be ion-doped. According to some embodiments, the upper surface of the first barrier layer 102 and a neighboring portion 102a thereof may be ion-doped. That is, the ion-doped portion of the first barrier layer 102 may be formed thin on the upper surface and the portion adjacent to the upper surface. According to some embodiments, the upper surface of the first barrier layer 102 and the neighboring portion 102a thereof may be greater than the central portion of the first barrier layer 102 or the lower surface (e.g., a surface in a −z direction) and the neighboring portion thereof in ion-doped concentration. Doped ions may be diffused to the surface (the upper surface) by a subsequent heat treatment. As shown in FIGS. 10 and 11 below, according to some embodiments, the heat treatment may be simultaneously (or concurrently) performed during an operation of forming the second substrate 103. According to some embodiments, doped ions may be fluorine (F) ions or boron (B) ions.

The second substrate 103 may be directly located on the upper surface of the first barrier layer 102. In the case where the second substrate 103 including polymer resin is directly located on the first substrate 101 including polymer resin, adhesive force between the first substrate 101 and the second substrate 103 is low, and thus, an exfoliation phenomenon may occur. According to some embodiments, the first barrier layer 102 may be located between the first substrate 101 and the second substrate 103 to compensate for low adhesive force between the first substrate 101 and the second substrate 103.

In addition, in the case where the second substrate 103 includes transparent polyimide as transparent polymer resin, unlike the case where the second substrate 103 includes yellow polyimide, adhesive force between the first substrate 101 and the second substrate 103 may be reduced due to physical properties such as film density, thermal expansion coefficient, and crystallinity. A floating or exfoliation phenomenon between the first barrier layer 102 and the second substrate 103 may occur.

In contrast, according to some embodiments, because a portion including the upper surface of the first barrier layer 102 is ion-doped, adhesive force between the first barrier layer 102 and the second substrate 103 directly located on the upper surface of the first barrier layer 102 may be improved. A floating or exfoliation phenomenon between the first barrier layer 102 and the second substrate 103 may be prevented. This is because the ion-doped portion on the upper surface of the first barrier layer 102 is in contact with the second substrate 103, and ions are diffused to interact electrostatically with the polymer resin (e.g., transparent polyimide) of the second substrate 103. It is estimated that bonding force between the first barrier layer 102 and the second substrate 103 increases.

According to some embodiments, adhesive force of the first barrier layer 102 may be 200 gf/inch or more. As an example, adhesive force between the first barrier layer 102 and the second substrate 103 may be 200 gf/inch or more. According to some embodiments, adhesive force of the first barrier layer 102 may be 230 gf/inch or more.

According to some embodiments, a second barrier layer 104 may be located on the second substrate 103. The second barrier layer 104 may include an inorganic insulating material such as silicon nitride, silicon oxynitride, and silicon oxide, and include a single-layered structure or a multi-layered structure including the above materials. According to some embodiments, the second barrier layer 104 and the first barrier layer 102 may include the same material. According to some embodiments, the second barrier layer 104 may include a material different from a material of the first barrier layer 102. According to some embodiments, the second barrier layer 104 may be omitted. The second barrier layer 104 may prevent or reduce instances of a material or impurities included in the substrate 100, for example, the first substrate 101 and the second substrate 103 penetrating elements on the substrate 100 and causing defects.

A buffer layer 105 may be located on the second barrier layer 105. According to some embodiments, the buffer layer 105 may include an inorganic insulating material such as silicon oxynitride and silicon nitride, and include a single-layered structure or a multi-layered structure including the above materials.

A sub-pixel circuit and a light-emitting diode electrically connected thereto may be located on the buffer layer 105. The sub-pixel circuit may include transistors and a storage capacitor. According to some embodiments, the sub-pixel circuit may include a first thin-film transistor TFT1, a second thin-film transistor TFT2, and a storage capacitor Cst.

According to some embodiments, a bottom metal layer BML may be located between the second barrier layer 104 and the buffer layer 105. The bottom metal layer BML may overlap the sub-pixel circuit to protect the sub-pixel circuit. The bottom metal layer BML may prevent or reduce instances of external light reaching the sub-pixel circuit. The bottom metal layer BML may include at least one material among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). According to some embodiments, the bottom metal layer BML may have a molybdenum-single layer, a double-layered structure in which a molybdenum layer and a titanium layer are stacked, or a triple-layered structure in which a titanium layer, an aluminum layer, and a titanium layer are stacked.

The second barrier layer 104, the bottom metal layer BML, and the buffer layer 105 may each be located between the second substrate 103 and the sub-pixel circuit and may prevent or reduce instances of the ions doped in the first barrier layer 102 influencing electrical characteristics of the first and second thin-film transistors TFT1 and TFT2 located on the buffer layer 105.

The first thin-film transistor TFT1 may be located on the buffer layer 105, wherein the first thin-film transistor TFT1 includes a first semiconductor layer A1 including a silicon semiconductor, a first gate electrode G1, a first source electrode S1, and a first drain electrode D1.

According to some embodiments, the first semiconductor layer A1 may include a silicon semiconductor. As an example, the first semiconductor layer A1 may include amorphous silicon (a-Si) or low-temperature polycrystalline silicon (LTPS) formed by crystallizing a-Si.

A first gate insulating layer 107 may be located on the first semiconductor layer A1. The first gate insulating layer 107 may include an inorganic insulating layer including an inorganic insulating material such as silicon oxide, silicon nitride and/or silicon oxynitride, and include a single layer or a multi-layered structure including the above material.

The first gate electrode G1 may be located on the first gate insulating layer 107. The first gate electrode G1 may include, for example, at least one metal among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and include a single layer or a multi-layer including the above metals.

A first interlayer insulating layer 109 may be provided to cover the first gate electrode G1. The first interlayer insulating layer 109 may include an inorganic insulating layer including an inorganic insulating material such as silicon oxide, silicon nitride and/or silicon oxynitride, and include a single layer or a multi-layered structure including the above material.

The storage capacitor Cst may be located on the first gate insulating layer 107. The storage capacitor Cst may include the first capacitor electrode CE1 and the second capacitor electrode CE2 overlapping the first capacitor electrode CE1. The first capacitor electrode CE1 of the storage capacitor Cst may overlap the second capacitor electrode CE2 with the first interlayer insulating layer 109 therebetween.

According to some embodiments, the first capacitor electrode CE1 of the storage capacitor Cst may overlap the first gate electrode G1 of the first thin-film transistor TFT1 and be provided integrally with the first gate electrode G1. According to some embodiments, the first capacitor electrode CE1 of the storage capacitor Cst may be apart from the first gate electrode G1 of the first thin-film transistor TFT1 and be located on the first interlayer insulating layer 109 as a separate independent element.

The second capacitor electrode CE2 of the storage capacitor Cst may include, for example, aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

A second interlayer insulating layer 111 may be located on the second capacitor electrode CE2. The second interlayer insulating layer 111 may include an inorganic insulating layer including an inorganic insulating material such as silicon oxide, silicon nitride and/or silicon oxynitride, and include a single layer or a multi-layered structure including the above material.

The second thin-film transistor TFT2 may be located on the buffer layer 105, wherein the second thin-film transistor TFT2 includes a second semiconductor layer A2, a lower gate electrode G2a, a second gate electrode G2b, a second source electrode S2, and a second drain electrode D2.

The lower gate electrode G2a may be located on the first interlayer insulating layer 109. According to some embodiments, the lower gate electrode G2a may be located on the same layer as a layer on which the second capacitor electrode CE2 is located. The lower gate electrode G2a may overlap at least a portion of the second semiconductor layer A2. The lower gate electrode G2a may be located below the second semiconductor layer A2 to protect the second semiconductor layer A2 and/or the second gate electrode G2b.

The second semiconductor layer A2 may be located on the second interlayer insulating layer 111. The second semiconductor layer A2 may include an oxide semiconductor. As an example, the second semiconductor layer A2 may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), or zinc (Zn). As an example, the second semiconductor layer A2 may include an ITZO (InSnZnO), an IGZO (InGaZnO), or the like.

A second gate insulating layer 113 may be located on the second semiconductor layer A2. The second gate insulating layer 113 may include an inorganic insulating layer including an inorganic insulating material such as silicon oxide, silicon nitride and/or silicon oxynitride, and include a single layer or a multi-layered structure including the above material.

The second gate electrode G2b may be located on the second gate insulating layer 113. The second gate electrode G2b may include, for example, at least one metal among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and include a single layer or a multi-layer including the above metals.

A third insulating layer 117 may be located on the second gate electrode G2. The third interlayer insulating layer 117 may include an inorganic insulating layer including an inorganic insulating material such as silicon oxide, silicon nitride and/or silicon oxynitride, and include a single layer or a multi-layered structure including the above material.

The first source electrode S1, the first drain electrode D1, the second source electrode S2, and the second drain electrode D2 may be located on the third interlayer insulating layer 117. The first source electrode S1, the first drain electrode D1, the second source electrode S2, and the second drain electrode D2 may each include, for example, a conductive material include molybdenum (Mo), aluminum (Al), copper (Cu), titanium (Ti), and the like, and include a multi-layer or a single layer including the above materials. According to some embodiments, the first source electrode S1, the first drain electrode D1, the second source electrode S2, and the second drain electrode D2 may each include have a multi-layered structure of Ti/Al/Ti.

A planarization layer 119 may be located on the first source electrode S1, the first drain electrode D1, the second source electrode S2, and the second drain electrode D2. The planarization layer 119 may include a general-purpose polymer such as benzocyclobutene (BCB), polyimide, hexamethyldisiloxane (HMDSO), polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. The planarization layer 119 may include silicon oxide, silicon nitride, silicon oxynitride, aluminum oxide, titanium oxide, tantalum oxide, hafnium oxide, or zinc oxide. After the planarization layer 119 is formed, chemical mechanical polishing may be performed to provide a flat upper surface. According to some embodiments, the planarization layer 119 may include a first planarization layer and a second planarization layer.

The organic light-emitting diode OLED as a light-emitting diode may be located on the planarization layer 119. The organic light-emitting diode OLED may include a sub-pixel electrode 210, an intermediate layer 220, and an opposite electrode 230.

The sub-pixel electrode 210 may be located on the planarization layer 119. The sub-pixel electrode 210 may be a (semi) light-transmissive electrode or a reflective electrode. The sub-pixel electrode 210 may include a reflective layer and a transparent or semi-transparent electrode layer formed on the reflective layer, wherein the reflective layer includes, for example, at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), and/or a compound thereof. The transparent or semi-transparent electrode layer may include at least one of indium tin oxide (ITO), indium zinc oxide (IZO), zinc oxide (ZnO), indium oxide (In₂O₃), indium gallium oxide (IGO), or aluminum zinc oxide (AZO). According to some embodiments, the sub-pixel electrode 210 may have a stack structure of ITO/Ag/ITO.

The bank layer 121 may be located on the planarization layer 119 and may include an opening exposing at least a portion of the sub-pixel electrode 210. A region exposed by the opening of the bank layer 121 may be defined as an emission area. The bank layer 121 may prevent or reduce instances of arcs and the like occurring at the edges of the sub-pixel electrode 210 by increasing a distance between the sub-pixel electrode 210 and the opposite electrode 230 over the sub-pixel electrode 210. The bank layer 121 may include an organic insulating material such as polyimide, polyamide, an acryl resin, benzocyclobutene, hexamethyldisiloxane (HMDSO), and a phenolic resin, and be formed by spin coating and the like. According to some embodiments, a spacer may be further located on the bank layer 121.

The intermediate layer 220 may be located on at least a portion of the pixel electrode 210 exposed by the bank layer 121. The intermediate layer 220 may include an emission layer. A first functional layer and a second functional layer may be selectively located under and on the emission layer.

The first functional layer may be located under the emission layer, and the second functional layer may be located on the emission layer. The first functional layer and the second functional layer located under and on the emission layer may be collectively referred to as organic functional layers.

The first functional layer may include a hole injection layer (HIL) and/or a hole transport layer (HTL), and the second functional layer may include an electron transport layer (ETL) and/or an electron injection layer (EIL).

The emission layer may include an organic material including a fluorescent or phosphorous material emitting red, green, blue, or white light. The emission layer may include a low molecular weight organic material or a polymer organic material.

In the case where the emission layer includes a low molecular weight organic material, the intermediate layer 220 may have a structure in which a hole injection layer, a hole transport layer, an emission layer, an electron transport layer, an electron injection layer, etc. are stacked in a single or composite configuration. The intermediate layer 220 may include, as a low molecular weight organic material, various organic materials such as copper phthalocyanine (CuPc), N, N′-Di (naphthalene-1-yl)-N, N′-diphenyl-benzidine (NPB), and tris-8-hydroxyquinoline aluminum (Alq3).

In the case where the emission layer include a polymer organic material, the intermediate layer 220 may generally have a structure including the hole transport layer and the emission layer. In this case, the HTL may include poly (3, 4-ethylenedioxythiophene) (PEDOT), and the EML may include a polymer material such as a polyphenylene vinylene (PPV)-based material and a polyfluorene-based material. The emission layer may be formed by screen printing, inkjet printing, laser induced thermal imaging (LITI), or the like.

The opposite electrode 230 may be located on the intermediate layer 220. The opposite electrode 230 is located on the intermediate layer 220 and may be located to cover the intermediate layer 220 entirely. The opposite electrode 230 is arranged in the display area DA and may be arranged to cover the display area DA entirely.

The opposite electrode 230 may include a conductive material having a low work function. As an example, the opposite electrode 230 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. Alternatively, the opposite electrode 230 may further include a layer on the (semi) transparent layer, the layer including ITO, IZO, ZnO, or In₂O₃.

According to some embodiments, a thin-film encapsulation layer 300 may be located on the organic light-emitting diode OLED. The thin-film encapsulation layer 300 may include at least one inorganic layer and at least one organic layer. According to some embodiments, the thin-film encapsulation layer 300 may include a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic insulating material, for example, silicon oxide, silicon nitride, silicon oxynitride, aluminum oxide, titanium oxide, tantalum oxide, hafnium oxide, and zinc oxide. The organic encapsulation layer 320 may include a polymer-based material. The polymer-based material may include, for example, polyethylene terephthalate, polyethylene naphthalate, polycarbonate, polyimide, polyethylene sulfonate, polyoxymethylene, polyarylate, hexamethyldisiloxane, an acryl-based resin (e.g., polymethylmethacrylate, poly acrylic acid, and the like), or an arbitrary combination thereof.

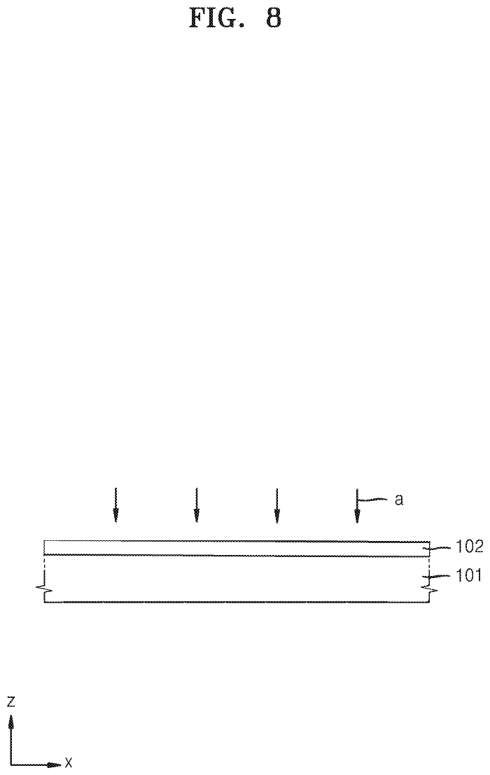

FIGS. 8 to 12 are schematic cross-sectional views showing a method of manufacturing a display apparatus according to some embodiments. Hereinafter, a method of manufacturing a display apparatus is sequentially described with reference to FIGS. 8 to 12.

Referring to FIG. 8, the first barrier layer 102 may be formed on the first substrate 101.

According to some embodiments, the first substrate 101 may include polymer resin. As an example, the first substrate 101 may include transparent polyimide. According to some embodiments, the first substrate 101 may be formed by coating a material for forming the first substrate and then curing the material for forming the first substrate through an ultraviolet process or a heat treatment.

According to some embodiments, the first barrier layer 102 may include at least one of silicon oxide, silicon nitride, or silicon oxynitride. As an example, the first barrier layer 102 may have a multi-layered structure of silicon oxynitride and silicon oxide. According to some embodiments, the first barrier layer 102 may be formed by using chemical vapor deposition (CVD). As an example, the first barrier layer 102 may be formed by using plasma enhanced chemical vapor deposition (PECVD).

Due to the differences in the material and the manufacturing method, the roughness of the upper surface of the first barrier layer 102 may be less than the roughness of the upper surface of the first substrate 101.

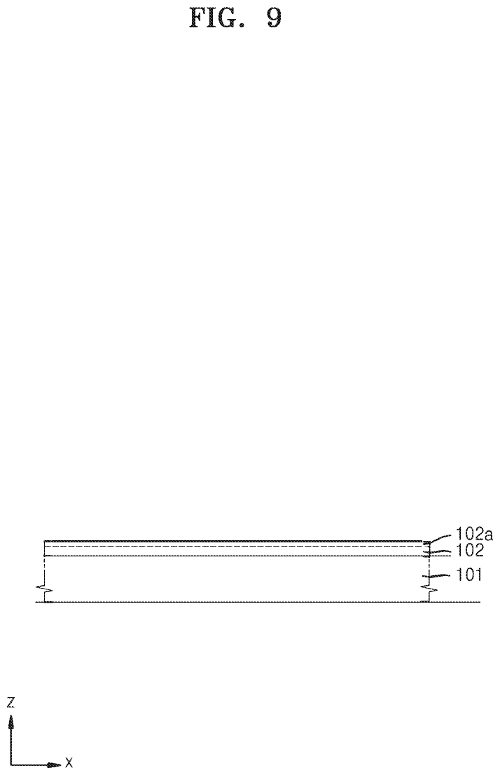

Referring to FIGS. 8 and 9, ions may be doped through the upper surface of the first barrier layer 102. According to some embodiments, an arrow a in FIG. 9 indicates ions are doped in the upper surface of the first barrier layer 102. Ions may be doped in the upper surface of the first barrier layer 102 entirely. The upper surface of the first barrier layer 102 and the neighboring portion 102a thereof may be ion-doped by doping. According to some embodiments, doped ions may be fluorine (F) ions or boron (B) ions.

According to some embodiments, the ion-doping operation may be performed at an acceleration voltage of about 3 KeV to about 15 KeV. According to some embodiments, the ion-doping operation may be performed at an acceleration voltage of about 5 KeV to about 10 KeV. The amount of doped ions and the position may change depending on the acceleration voltage. In the case where the acceleration voltage deviates from the above range, for example, in the case where the acceleration voltage in the ion-doping operation is less than 3 KeV, the amount of ions doped in the portion including the upper surface of the first barrier layer 102 is small, and an adhesive force improvement effect between the first barrier layer 102 and the second substrate 103 may be trivial. When the acceleration voltage in the ion-doping operation exceeds 15 KeV, the ions may be located on the central portion or a portion adjacent to the lower surface of the first barrier layer 102, not the upper surface of the first barrier layer 102 and the neighboring portion 102a thereof. In addition, when the amount of doped ions increase, the ions may influence electrical characteristics and the like of the thin-film transistor over the substrate 100.

According to some embodiments, the amount of ions doped in the upper surface of the first barrier layer 102 may be 1×10¹⁵/cm² to about 1×10¹³/cm². As an example, the amount of ions doped in the upper surface of the first barrier layer 102 may be 1×10¹⁴/cm².

Referring to FIGS. 10 and 11, the second substrate 103 may be formed on the first barrier layer 102. According to some embodiments, the second substrate 103 may include polymer resin. As an example, the second substrate 103 may include polyimide. According to some embodiments, the second substrate 103 may be formed by coating a material 103′ for forming the second substrate and then curing the material 103′ for forming the second substrate through an ultraviolet process or a heat treatment process. As an example, the material 103′ for forming the second substrate may be cured through heat treatment. An arrow b shown in FIG. 10 indicates heat is applied to the material 103′ for forming the second substrate.

According to some embodiments, during the process of heat-treating the material 103′ for forming the second substrate, the ions doped in the upper surface of the first barrier layer 102 and the neighboring portion 102a thereof may diffuse toward the upper surface of the first barrier layer 102. Because a separate heat treatment process for diffusing doped ions is not performed, the process may be relatively economical. However, the embodiments according to the present disclosure are not limited thereto. According to some embodiments, the first barrier layer 102 may be heat-treated before the second substrate 103 is formed. Ions existing on the upper surface of the first barrier layer 102 may contribute to bonding force or adhesive force improvement with the second substrate 103. According to some embodiments, because the portion including the upper surface of the first barrier layer 102 is ion-doped, adhesive force between the first barrier layer 102 and the second substrate 103 may be improved during a process in which the second substrate 103 is formed on the upper surface of the first barrier layer 102.

According to some embodiments, the operation of heat-treating the material 103′ for forming the second substrate may be performed at temperature of about 360° C. to about 460° C. According to some embodiments, the heat-treating may be performed at temperature of about 410° C. to about 450° C. In the case where the heat-treatment temperature deviates from the above range, for example, in the case where the heat-treatment temperature exceeds 460° C., the material 103 for forming the second substrate may be denatured, and thus, the second substrate 103 that is colored may be formed. The transparence and the transmittance of the second substrate 103 may be reduced. In contrast, when the heat treatment temperature is less than 360° C., the physical properties of the second substrate 103 such as crystallinity and the like may be deteriorated. Accordingly, bonding force between the second substrate 103 and the first barrier layer 102 may be reduced.

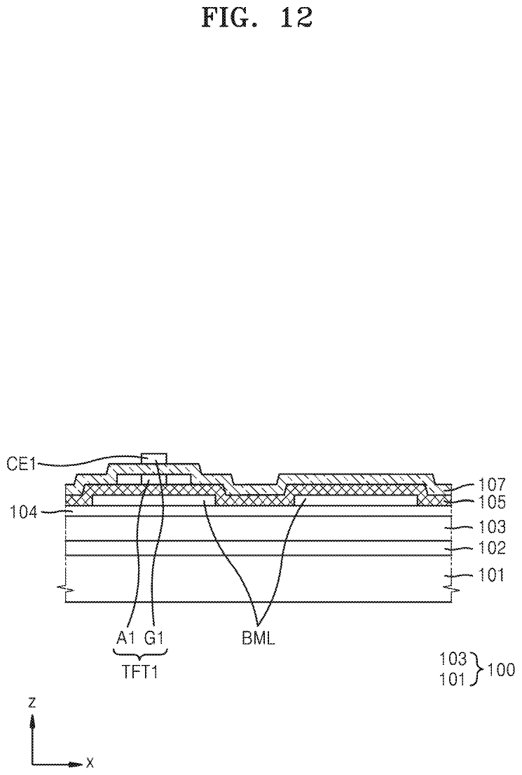

Referring to FIG. 12, the second barrier layer 104, the bottom metal layer BML, and the buffer layer 105 may be sequentially formed on the second substrate 103. Then, the first thin-film transistor TFT1 may be formed on the buffer layer 105, wherein the first thin-film transistor TFT1 includes the first semiconductor layer A1 including a silicon semiconductor, and the first gate electrode G1 insulated from the first semiconductor layer A1.

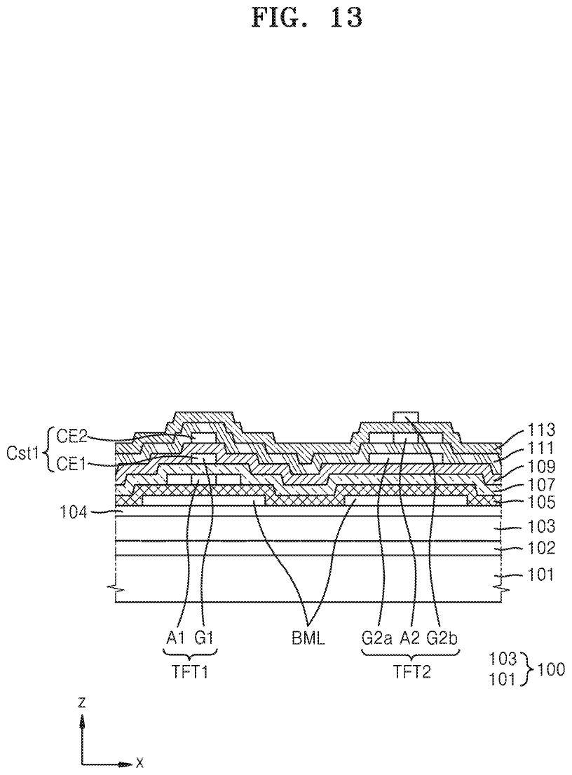

Referring to FIG. 13, the first interlayer insulating layer 109 may be formed on the first gate electrode G1. Then, the second thin-film transistor TFT2 may be further formed on the first interlayer insulating layer 109, wherein the second thin-film transistor TFT2 includes the second semiconductor layer A2 including an oxide semiconductor, and the second gate electrode G2b insulated from the second semiconductor layer A2.

According to some embodiments, the organic light-emitting diode OLED (see FIG. 6) may be formed on the second thin-film transistor TFT2. The organic light-emitting diode OLED may include the sub-pixel electrode 210 (see FIG. 6), the intermediate layer 220 (see FIG. 6), and the opposite electrode 230 (see FIG. 6).

As described above, the second barrier layer 104, the bottom metal layer BML, and the buffer layer 105 may each be located between the second substrate 103 and the sub-pixel circuit and may prevent the ions doped in the first barrier layer 102 from influencing electrical characteristics of the first and second thin-film transistors TFT1 and TFT2 and/or the organic light-emitting diode OLED located on the buffer layer 105.

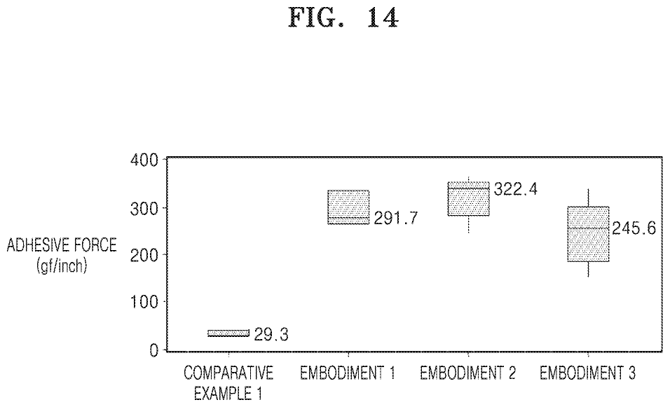

FIG. 14 is a graph showing results of analyzing adhesive force of the first barrier layer according to Embodiments 1 to 3 and adhesive force of Comparative Example 1.

The first barrier layer 102 according to Embodiments 1 to 3 includes silicon oxide, and fluorine (F) ions or boron (B) icons are doped in the portion including the upper surface of the first barrier layer 102. The first barrier layer 102 according to embodiments 1 to 3 was manufactured by performing doping at an acceleration voltage of about 5 KeV or about 10 KeV. For example, in Embodiment 1, the doping was performed at an acceleration voltage of about 5 KeV using boron (B) ions as dopants, in Embodiment 2, the doping was performed at an acceleration voltage of about 10 KeV using boron (B) ions as dopants, and in Embodiment 3, the doping was performed at an acceleration voltage of about 5 KeV using fluorine (B) ions as dopants. The second substrate 103 was formed on the upper surface of the first barrier layer 102 in Embodiments 1 to 3. In the process of forming the second substrate 103, heat treatment was performed at temperature of about 410° C. to about 450° C. The second substrate 103 includes transparent polyimide.

The first barrier layer of Comparative Example 1 includes silicon oxide and the ion doping was not performed thereon. The second substrate was formed on the first barrier layer of Comparative Example 1. During the process of forming the second substrate, heat treatment was performed at the same temperature as the temperature of Embodiments 1 to 3. The second substrate includes transparent polyimide.

Referring to FIG. 14, it is determined that adhesive force between the first barrier layer 102 and the second substrate 103 according to Embodiments 1 to 3 is excellent compared with adhesive force between the first barrier layer and the second substrate according to Comparative Example 1. For example, adhesive force of the first barrier layer according to Comparative Example 1 is about 30 gf/inch, but adhesive force of the first barrier layer 102 according to Embodiments 1 to 3 may be about 200 gf/inch or more. As an example, adhesive force between the first barrier layer 102 and the second substrate 103 according to Embodiment 1 is about 291.6 gf/inch, adhesive force between the first barrier layer 102 and the second substrate 103 according to Embodiment 2 is about 322.4 gf/inch, and adhesive force between the first barrier layer 102 and the second substrate 103 according to Embodiment 3 is about 245.6 gf/inch, which are 6 times greater than adhesive force of the first barrier layer according to Comparative Example 1.

Therefore, according to some embodiments, because the portion including the upper surface of the first barrier layer 102 is ion-doped, for example, doped with fluorine (F) ions or boron (B) ions, adhesive force the first barrier layer 102 and the second substrate 103 directly located on the upper surface of the first barrier layer 102 may be improved.

The display apparatus according to some embodiments includes the substrate including transparent polymer resin, secures a transmittance, and improves adhesive force between the substrate and the barrier layer, thereby preventing or reducing instances of a floating or exfoliation phenomenon between the substrate and the barrier layer. However, the scope of embodiments according to the present disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a first substrate including a polymer resin;
a first barrier layer on the first substrate and including a portion doped with ions, wherein the portion includes an upper surface of the first barrier layer;
a second substrate on the upper surface of the first barrier layer and including a polymer resin;
a buffer layer on the second substrate;
a first thin-film transistor on the buffer layer; and
a light-emitting diode electrically connected to the first thin-film transistor.

2. The display apparatus of claim 1, wherein the first barrier layer includes at least one of silicon oxide, silicon nitride, or silicon oxynitride.

3. The display apparatus of claim 1, wherein the ions include fluorine ions or boron ions.

4. The display apparatus of claim 1, wherein the second substrate includes transparent polyimide.

5. The display apparatus of claim 1, wherein adhesive force of the first barrier layer is 200 gf/inch or more.

6. The display apparatus of claim 1, wherein the first thin-film transistor includes:
a first semiconductor layer including a silicon semiconductor; and
a first gate electrode insulated from the first semiconductor layer.

7. The display apparatus of claim 6, further comprising:
an insulating layer covering the first gate electrode; and
a second thin-film transistor on the insulating layer and including a second semiconductor layer and a second gate electrode insulated from the second semiconductor layer, wherein the second semiconductor layer includes an oxide semiconductor.

8. The display apparatus of claim 7, further comprising a bottom metal layer between the second substrate and the buffer layer.

9. The display apparatus of claim 1, further comprising a second barrier layer between the second substrate and the buffer layer.

10. A method of manufacturing a display apparatus, the method comprising:
preparing a first substrate including a polymer resin;
forming a first barrier layer on the first substrate;
doping an upper surface of the first barrier layer with ions such that a portion including the upper surface of the first barrier layer is ion-doped;
forming a second substrate on the upper surface of the first barrier layer, wherein the second substrate includes a polymer resin;
forming a buffer layer on the second substrate; and
forming a first thin-film transistor and a light-emitting diode on the buffer layer, wherein the light-emitting diode is electrically connected to the first thin-film transistor.

11. The method of claim 10, wherein the first barrier layer includes at least one of silicon oxide, silicon nitride, or silicon oxynitride.

12. The method of claim 10, wherein the ions include fluorine ions or boron ions.

13. The method of claim 10, wherein the doping of the upper surface of the first barrier layer with the ions is performed at an acceleration voltage in a range of 5 KeV to 10 KeV.

14. The method of claim 10, wherein the forming of the second substrate includes:
coating a material for forming the second substrate, on the upper surface of the first barrier layer; and
heat-treating the material for forming the second substrate.

15. The method of claim 14, wherein the heat-treating is performed at temperature in a range of 410° C. to 450° C.

16. The method of claim 10, wherein the second substrate includes transparent polyimide.

17. The method of claim 10, wherein an adhesive force of the first barrier layer is 200 gf/inch or more.

18. The method of claim 10, wherein the forming of the first thin-film transistor includes forming the first thin-film transistor including a first semiconductor layer including a silicon semiconductor and a first gate electrode insulated from the first semiconductor layer.

19. The method of claim 18, further comprising:
forming an insulating layer on the first gate electrode; and
forming a second thin-film transistor on the insulating layer, wherein the second thin-film transistor includes a second semiconductor layer and a second gate electrode insulated from the second semiconductor layer, and the second semiconductor layer includes an oxide semiconductor.

20. The method of claim 10, further comprising forming a bottom metal layer between the second substrate and the buffer layer.
